(19) United States
(12) Patent Application Publication
(10) Pub. No.: US 2005/0012226 A1
(43) Pub. Date: Jan. 20, 2005

(54) Chip package structure

(76) Inventors: Kenny Chang, Hsin-Tien City (TW); Hung-Yin Tsai, Hsin-Tien City (TW); Nicola Li, Hsin-Tien City (TW)

Correspondence Address: J C PATENTS, INC., 4 VENTURE, SUITE 250, IRVINE, CA, 92618, US

(21) Appl. No.: 10/737,011

(22) Filed: Dec. 15, 2003

(30) Foreign Application Priority Data
Jul. 16, 2003 (TW) 92212987

(51) Int. Cl. H01L 21/302

(52) U.S. Cl. 257/784; 257/690

(57) ABSTRACT

A chip package structure comprising a carrier, a chip, a plurality of passive components, a plurality of conductive wires and some insulating material is provided. The passive components are attached to the surface of the carrier with its electrodes connected to a power contact and a ground contact respectively. The conductive wires cross over the passive components with its ends connected respectively to a bonding pad on the chip and a signal contact close to the edge of the carrier. With the wires crossing over the passive components that are positioned close to a chip bonding area of the carrier, contact between the wires and the electrodes is prevented and the space for accommodating conductive wires is increased.

### CROSS-REFERENCE TO RELATED APPLICATION

This application claims the priority benefit of Taiwan application serial no. 92212987, filed on Jul. 16, 2003.

### BACKGROUND OF THE INVENTION

1. Field of the Invention

The present invention relates to a chip package structure. More particularly, the present invention relates to a wire-bonding chip package structure with passive components.

2. Description of the Related Art

With the rapid progress in semiconductor fabrication technologies, faster and more accurate electronic devices continue to appear in the market. At present, semiconductor packaging technology is a major area in research and development. The techniques of IC packaging, chip carrier manufacturing and surface mounting are important topics in the production of semiconductors.

In the packing of chips, each chip sawn out from a wafer must be attached to a carrier surface and electrically connected through wire bonding or flip chip bonding, for example. The carrier is a lead frame or a substrate, for example. The active surface of the chip has a plurality of bonding pads for connecting the chip to external electronic devices via contacts and transmission circuits in the carrier. After the ends of conductive wires are bonded to the bonding pads and corresponding contacts on the substrate, insulating material is injected to enclose and protect the chip and the conductive wires.

FIG. 1 is a schematic cross-sectional view showing a portion of a conventional wire-bonded chip package. As shown in FIG. 1, the chip package 100 mainly comprises a carrier 110, a chip 120, a plurality of conductive wires 134, 136, 138 and some insulating material (not shown). The carrier 110 has a chip bonding area 112 on one of the surfaces. The backside 122 of the chip 120 is attached to the chip bonding area 112. Furthermore, the active surface 124 of the chip 120 has a plurality of bonding pads 126 thereon that matches a plurality of contacts on the surface of the carrier 110. Ground contacts 114, power source contacts 116 and signal contacts 118 are arranged such that the ground contacts 114 are closest to the bonding area 112 and the signal contacts are furthest from the bonding area 112. The two ends of the conductive wires 134, 136, 138 connect the bonding pads 126 on the chip 120 with corresponding ground contacts 114, power contacts 116 and signal contacts 118.

FIG. 2 is a top view of the chip package structure in FIG. 1. To improve the electrical properties of the chip package structure 100, surface mount technology (SMT) is normally used to attach small passive components 140 on the surface of the carrier 110. Moreover, the passive components 140 are positioned close to the corner regions for reducing the amount of cross talk between conductive wires so that a high transmission quality is maintained. The passive components 130 are inductors or capacitors, for example. In general, the passive components 130 straddle on the surface of the carrier 110 between the power contacts 116 and the ground contacts 114. The electrodes 132a, 132b of the passive components 130 are connected to a power contact 116 and a ground contact 114 respectively.

However, due to the limited space for accommodating the conductive wires, all the passive components 130 are set up on the carrier 110 close to the corner regions of the chip 120. Alternatively, the passive components 130 are placed far away from the chip bonding area 112 of the carrier 110 and between the signal contacts 118. With this spatial arrangement, the signal wire 138 is prevented from contacting the electrodes 132a, 132b of the passive components 130 to cause a short circuit.

### SUMMARY OF THE INVENTION

Accordingly, one object of the present invention is to provide a chip package structure having conductive wires directly crossing over passive components. Hence, the number of passive components inside the package can be increased without affecting the layout of the conductive wires.

To achieve these and other advantages and in accordance with the purpose of the invention, as embodied and broadly described herein, the invention provides a chip package structure. The chip package comprises a carrier having a surface with at least a power contact, a ground contact and a signal contact thereon. Furthermore, the surface of the chip package has a chip bonding area. The power contact and the ground contact are located within the peripheral region of the chip bonding area. The signal contact is located in a region further away from the power contact and the ground contact. A chip having an active surface and a corresponding backside is provided. The backside of the chip is attached to the chip bonding area of the carrier. The active surface of the chip has a plurality of bonding pads thereon. In addition, at least a passive component is attached to the surface of the carrier between the power contact and the ground contact. The passive component has at least two electrodes connected to a power contact and a ground contact respectively. A plurality of first conductive wires is provided. An end of each first conductive wire is bonded to one of the bonding pads on the chip and another end of the first conductive wire is bonded to a corresponding power contact or a ground contact. Similarly, at least a second conductive wire is provided. An end of the second conductive wire is bonded to another bonding pad on the chip and another end of the second conductive wire is bonded to a corresponding signal contact. Moreover, the second conductive wire crosses over the passive component. Some insulating material encloses the chip, the passive component, the first conductive wires and the second conductive wire.

This invention also provides a chip carrier structure having a surface with at least a power contact, a ground contact and a signal contact thereon. The surface of the carrier has a chip bonding area. The power contact and the ground contact are located within the peripheral region of the chip bonding area. The signal contact is located in a region further away from the power contact and the ground contact. In addition, at least a passive component is attached to the surface of the carrier between the power contact and the ground contact. The passive component has at least two electrodes connected to a power contact and a ground contact respectively. Moreover, the passive component is positioned within a region between the chip bonding area and corresponding signal contacts on the carrier.

In this invention, the passive components of the chip package structure are designed to be close to the chip bonding area of the carrier so that the conductive wires can cross over the passive components. With this setup, the conductive wires are prevented from contacting the electrodes of the passive components and the area for accommodating the conductive wires is increased.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view showing a portion of a conventional wire-bonded chip package.

FIG. 2 is a top view of the chip package structure in FIG. 1.

FIG. 3A is a top view of a chip package structure according to one preferred embodiment of this invention.

FIG. 3B is a schematic cross-sectional view of a portion of the chip package structure shown in FIG. 3A.

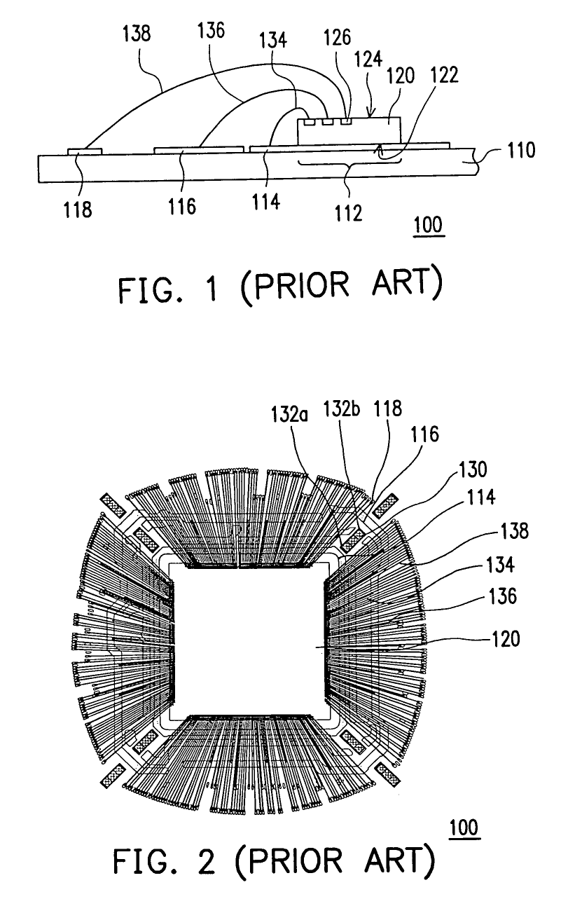

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

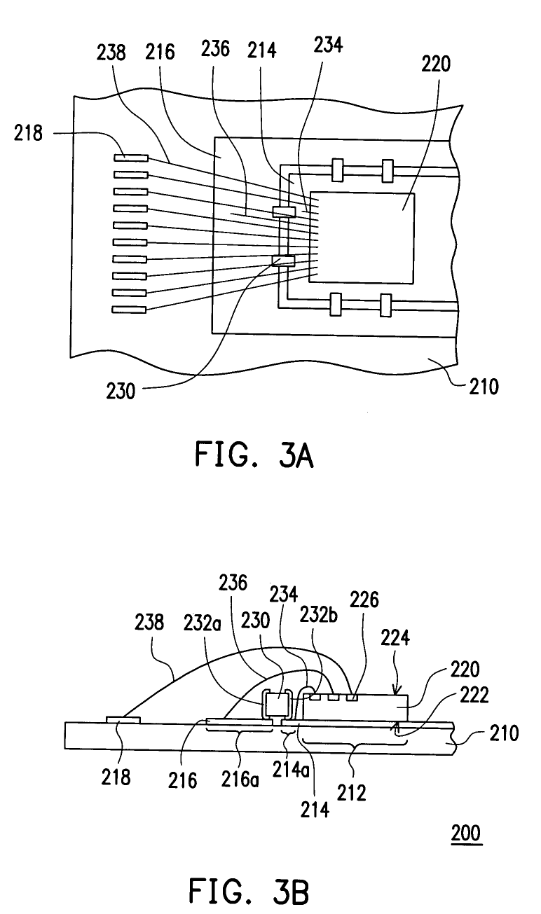

FIG. 3A is a top view of a chip package structure according to one preferred embodiment of this invention. FIG. 3B is a schematic cross-sectional view of a portion of the chip package structure shown in FIG. 3A. As shown in FIGS. 3A and 3B, a chip package structure 200 is provided. The chip package structure 200 comprises a carrier 210, a chip 220, a plurality of passive components 230, a plurality of first conductive wires 234, 236, a plurality of second conductive wires 238 and some insulating material (not shown). The carrier 210 is a substrate having a chip bonding area 212 on one surface, for example. The chip 220 has an active surface 224 with a plurality of bonding pads 226 thereon that correspond with the plurality of contacts on the surface of the carrier 210. The contacts are ground contacts 214a, power contacts 216a and signal contacts 218, for example.

In this embodiment, the power contacts 216a and the ground contacts 214a are formed of a power ring 216 and a ground ring 214, respectively. It should be noted that the power ring 216 and the ground ring 214 are located around and most close to the chip bonding area 212. These power contacts 216a and ground contacts 214a serve as points of contact with the first conductive wires 234, 236 or the passive components 230 (as shown in FIG. 3B). The signal contacts 218 are located on one side further away from the power contacts 216a and the ground contacts 214a. The exposed areas of the power contacts 216a, ground contacts 214a, signal contacts 218 and the chip bonding area 212 may be defined by a patterned solder mask (not shown).

The passive components 230 are positioned between a power contact 216a and a ground contact 214a. Each passive component 230 has at least two electrodes 232a and 232b. The electrodes 232a and 232b are bonded respectively to the power contact 216a and the ground contact 214a through surface mount technology (SMT) so that interference due to signal transmission is reduced and transmission quality within the package is maintained. The passive components 230 are inductors or capacitors, for example. In general, the passive components 230 are set up within the region between the chip bonding area 212 and the signal contacts 218. Furthermore, the passive components 230 are located close to the chip bonding area 212 so that its presence will not affect the layout of the second conductive wires 238. Hence, the second conductive wires 238 may cross over the passive components 230 in an arc largely prevented from contacting the electrode 232a. In other words, the arrangement of the passive components 230 is able to increase the spatial utilization of the carrier 210. In addition, the first conductive wires 236 are also permitted to cross over the passive component 230. One end of the first conductive wire 236 is bonded to a power contact 216a while one end of another first conductive wire 234 is bonded to a ground contact 214a besides the passive components 230.

Accordingly, to form the chip package structure of this invention, at least a passive component is positioned on the carrier close to the chip with its electrodes bonded to a power contact and a ground contact respectively. Thereafter, the ends of a first conductive wire are bonded respectively to a bonding pad on the chip and a corresponding power contact or ground contact. Similarly, the ends of a second conductive wire are bonded respectively to another bonding pad on the chip and a corresponding signal contact on the outlying regions of the carrier so that the second conductive wire crosses over the passive component. Finally, some insulating material is injected to enclose the chip, the first conductive wires and the second conductive wires and form a complete chip package.

In summary, the chip package structure according to this invention has at least the following advantages:
1. The passive components are positioned under the conductive wires and hence the conductive wires are prevented from contacting the electrodes of the passive components. Furthermore, the passive components are arranged close to one side of the chip bonding area so that the number of passive components that can be accommodated is increased without affecting wiring layout. Consequently, spatial utilization of the carrier is increased.
2. The electrodes of the passive components underneath the conductive wires are bonded to a power contact and a ground contact on the surface of the carrier. In other words, the electrodes of the passive components are very close to the contacts with the power conductive wires and the ground conductive wires. Hence, interference due to signal transmission is minimized and electrical performance of the chip package is improved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A chip package structure, comprising:
a carrier having a surface with a power contact, a ground contact and a signal contact thereon, wherein the surface also has a chip bonding area, the power contact and the ground contact are located close to the chip bonding area but the signal contact is positioned further away from the chip bonding area;
a chip having an active surface and a backside such that the backside of the chip is attached to the chip bonding area of the carrier, wherein the active surface of the chip has a plurality of bonding pads thereon;
at least a passive component having at least two electrodes positioned on the carrier such that the electrodes are bonded to said power contact and said ground contact respectively;
a plurality of first conductive wires with the two ends of each conductive wire connected to one of the bonding pads of the chip and said power contact or said ground contact;
at least a second conductive wire with the two ends connected one of the bonding pads of the chip and a corresponding signal contact such that the second conductive wire crosses over the passive component; and
an insulating material that encloses the chip, the passive component, the first conductive wires and the second conductive wire.

2. The chip package structure of claim 1, wherein at least one of the first conductive wires crosses over the passive component while the remaining first conductive wires are adjacent to the passive component.

3. The chip package structure of claim 1, wherein the passive component is selected form one of an inductor and a capacitor.

4. A chip carrier structure suitable for a wire-bonding package, the chip carrier structure comprising:
a carrier with a surface having a power contact, a ground contact and a signal contact thereon, wherein the surface also has a chip bonding area, the power contact and the ground contact are located close to the chip bonding area but the signal contact is positioned further away from the chip bonding area; and
at least a passive component having at least two electrodes positioned on the carrier such that the electrodes are bonded to the power contact and the ground contact respectively and the passive component is located within a region between the chip bonding area and the signal contact.

5. The chip carrier structure of claim 4, wherein the passive component is selected form one of an inductor and a capacitor.

6. A chip package structure, comprising:
a carrier having a surface with a power ring, a ground ring and a plurality of signal contacts thereon, wherein the surface also has a chip bonding area, the power ring and the ground ring are located around and most close to the chip bonding area, the signal contacts are positioned further away from the chip bonding area, the power ring has a plurality of power contacts, the ground ring has a plurality of ground contacts;
a chip having an active surface and a backside such that the backside of the chip is attached to the chip bonding area of the carrier, wherein the active surface of the chip has a plurality of bonding pads thereon;
at least a passive component having at least two electrodes positioned on the carrier such that the electrodes are bonded to one of the power contacts and one of the ground contacts respectively;
a plurality of first conductive wires with the two ends of each conductive wire connected to one of the bonding pads of the chip and one of the power contacts or one of the ground contacts;
at least a second conductive wire with the two ends connected one of the bonding pads of the chip and one of the signal contacts such that the second conductive wire crosses over the passive component; and
an insulating material that encloses the chip, the passive component, the first conductive wires and the second conductive wire.

7. The chip package structure of claim 6, wherein at least one of the first conductive wires crosses over the passive component while the remaining first conductive wires are adjacent to the passive component.

8. The chip package structure of claim 6, wherein the passive component is selected form one of an inductor and a capacitor.

9. A chip carrier structure suitable for a wire-bonding package, the chip carrier structure comprising:
a carrier with a surface having a power ring, a ground ring and a plurality of signal contacts thereon, wherein the surface also has a chip bonding area, the power ring and the ground ring are located around and most close to the chip bonding area, the signal contacts are positioned further away from the chip bonding area, the power ring has a plurality of power contacts, the ground ring has a plurality of ground contacts; and
at least a passive component having at least two electrodes positioned on the carrier such that the electrodes are bonded to one of the power contacts and one of the ground contacts respectively.

10. The chip carrier structure of claim 9, wherein the passive component is selected form one of an inductor and a capacitor.

11. A chip carrier suitable for a wire-bonding package, the chip carrier comprising a power ring, a ground ring and a plurality of signal contacts on a surface of the chip carrier, wherein the surface also has a chip bonding area, the power ring and the ground ring are located around and most close to the chip bonding area, the signal contacts are positioned further away from the chip bonding area, the power ring has at least a power contact for bonding to an electrode of a passive component, the ground ring has at least a ground contact for bonding to another electrode of the passive component.
